(19) United States
(12) Patent Application Publication
(10) Pub. No.: US 2025/0007486 A1
(43) Pub. Date: Jan. 2, 2025

(54) ACOUSTIC WAVE DEVICES AND MODULES USING SAME

(71) Applicant: Sanan Japan Technology Corporation, Tokyo (JP)

(72) Inventors: SUBEI SHUN, Tokyo (JP); Hiroshi Nakamura, Tokyo (JP); Shinichi Shioi, Tokyo (JP)

(73) Assignee: Sanan Japan Technology Corporation, Tokyo (JP)

(21) Appl. No.: 18/754,717

(22) Filed: Jun. 26, 2024

(30) Foreign Application Priority Data
Jun. 30, 2023 (JP) 2023-107738

(51) Int. Cl. H03H 9/02; H03H 3/10; H03H 9/25

(52) U.S. Cl. CPC H03H 9/02574; H03H 9/02228; H03H 9/02559; H03H 9/25; H03H 3/10

(57) ABSTRACT

An acoustic wave device includes a support substrate, a medium layer formed on the support substrate, a piezoelectric substrate formed on the medium layer, and a resonator including IDT electrodes formed on the piezoelectric substrate. The medium layer includes stripe-shaped first acoustic impedance regions having a longitudinal direction and a lateral direction, and stripe-shaped second acoustic impedance regions having a longitudinal direction and a lateral direction and an acoustic impedance different from that of the first acoustic impedance regions, which are alternately arranged with the first acoustic impedance region.

### CROSS-REFERENCE TO RELATED APPLICATION(S)

This application claims priority to Japanese Application No. 2023-107738, filed Jun. 30, 2023, which are incorporated herein by reference, in their entirety, for any purpose.

### BACKGROUND OF THE INVENTION

### Field of the Invention

The present disclosure relates to an acoustic wave device and a module including the acoustic wave device. More specifically, the present disclosure relates to a surface acoustic wave device using SH wave, such as a filter, a duplexer, or a multiplexer.

### Background Art

High-frequency communication system for mobile communication terminals typified by smartphones adopts a high-frequency filter or the like to remove unnecessary signals other than signals in the frequency band used for communication.

The acoustic wave device having a surface acoustic wave (SAW: Surface Acoustic Wave) element is used as a high-frequency filter or the like. The SAW element is the element that includes IDT (Interdigital Transducer) having a pair of comb-shaped electrodes on a piezoelectric substrate.

Surface acoustic wave devices are produced as follows. A piezoelectric substrate propagating an acoustic wave and a multilayer film substrate bonding a support substrate having thermal expansion coefficient lower than that of the piezoelectric substrate are formed. Next, a plurality of IDT electrodes are formed on the multilayer film substrate using a photolithography technique, and then a surface acoustic wave device is cut into a predetermined size by dicing. The support substrate suppresses the change in the size of the piezoelectric substrate when the temperature changes by using the multilayer film substrate, as a result, this producing method can stabilize frequency characteristic of the acoustic wave device.

According to Patent Document 1 (JP2009-278610) and the like, in order to improve the temperature characteristics of an acoustic wave device, it is known that a support substrate such as a sapphire substrate having a high Young's modulus and a low linear expansion coefficient is bonded to a piezoelectric substrate to suppress expansion and contraction due to temperature change.

As disclosed in Patent Document 1, in order to improve the temperature characteristics of an acoustic wave device, it is known that a support substrate such as a sapphire substrate having a high Young's modulus and a low linear expansion coefficient is bonded to a piezoelectric substrate to suppress expansion and contraction due to temperature change. However, spurious wave sometimes occurs particularly on the high-frequency side in such support substrate, and the filter characteristics are inferior.

### SUMMARY OF THE INVENTION

Some examples described herein may address the above-described problems. Some examples described herein may have an object to provide an acoustic wave device having a superior temperature characteristic and a more suppressed spurious property, and a module including the acoustic wave device.

In some examples, an acoustic wave device includes a support substrate, a medium layer formed on the support substrate, a piezoelectric substrate formed on the medium layer, and a resonator including IDT electrodes formed on the piezoelectric substrate. The medium layer includes stripe-shaped first acoustic impedance regions having longitudinal directions and lateral directions, and stripe-shaped second acoustic impedance regions having longitudinal directions and lateral directions and an acoustic impedance different from that of the first acoustic impedance regions, which are alternately arranged with the first acoustic impedance regions.

### BRIEF DESCRIPTION OF THE DRAWING

FIG. 1 is a cross-sectional view of an acoustic wave device 1 according to a first embodiment.

FIG. 2 is a cross-sectional view showing a device chip 5 of the acoustic wave device 1 according to the first embodiment.

FIG. 3 is a top view of a functional element 50 of the acoustic wave device 1 according to the first embodiment.

FIG. 4 is a diagram illustrating resonance characteristics of a resonator of the acoustic wave device 1 according to the first embodiment and a resonator of the comparative example.

FIG. 5 is a diagram (part 2) illustrating the resonance characteristics of the resonator of the acoustic wave device 1 according to the first embodiment and the resonator of the comparative example.

FIG. 6 is a diagram illustrating the resonance characteristics of the resonator (five periods within the range of eight electrode fingers, and others) of the acoustic wave device 1 according to the first embodiment.

FIG. 7 is a diagram illustrating the resonance characteristics of the resonator (six periods within the range of eight electrode fingers, and others) of the acoustic wave device 1 according to the first embodiment.

FIG. 8 is a cross-sectional view showing a configuration in which five second acoustic impedance regions 12 B are arranged within the range of eight electrode fingers 51b.

FIG. 9 is a top view of a functional element 50 of the acoustic wave device 1 according to a second embodiment.

FIG. 10 is a diagram for explaining a method for producing the acoustic wave device 1.

FIG. 11 is a diagram for explaining a method for producing the acoustic wave device 1 according to the second embodiment.

FIG. 12 is a longitudinal sectional view of a module to which the acoustic wave device 1 is applied according from the first embodiment to the third embodiment.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

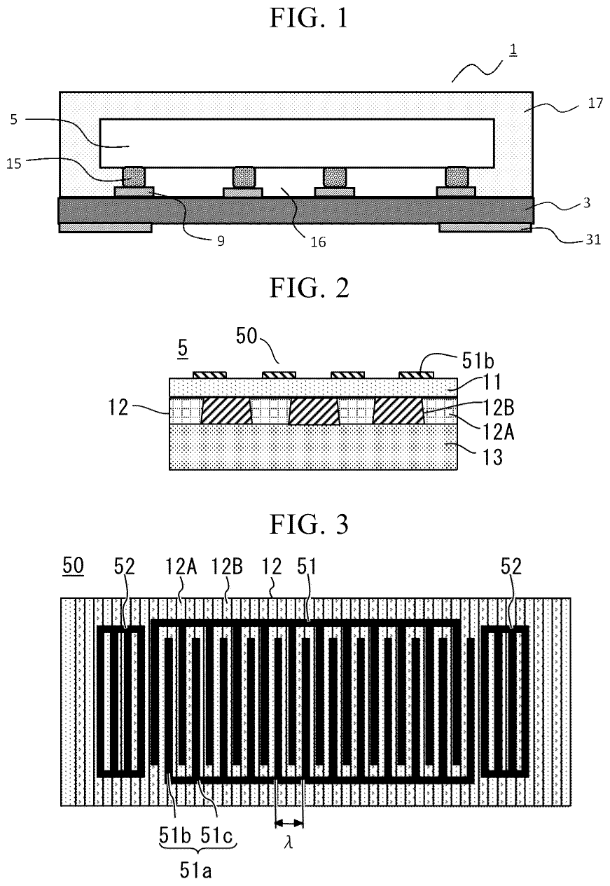

FIG. 1 is a cross-sectional view of an acoustic wave device 1 according to a first embodiment.

As shown in FIG. 1, the acoustic wave device 1 includes a wiring substrate 3, external connection terminals 31, a device chip 5, electrode pads 9, bumps 15, and a sealing portion 17.

The wiring substrate 3 is a multilayer substrate made of resin. For example, the wiring substrate 3 is a low-temperature co-fired ceramic (Low Temperature Co-Fired Ceramics:LTCC) multilayer substrate includes a plurality of dielectric layers.

The plurality of external connection terminals 31 are formed on the lower surface of the wiring substrate 3.

The plurality of electrode pads 9 are formed on the main surface of the wiring substrate 3. For example, the electrode pads 9 are formed of copper or an alloy containing copper. For example, the electrode pads 9 have the thickness of 10 μm to 20 μm.

The bumps 15 are formed on each upper surface of the electrode pads 9. The bumps 15 are gold bumps for example. The bump 15 has the height of 10 μm to 50 μm for example.

An air gap 16 is formed between the wiring substrate 3 and the device chip 5.

The device chip 5 is mounted on the wiring substrate 3 via the bumps 15 by flip-chip bonding. The device chip 5 is electrically connected to the plurality of electrode pads 9 via the plurality of bumps 15.

The device chip 5 is a substrate on which acoustic wave elements 50 are formed. For example, a transmission filter and a reception filter including the plurality of acoustic wave elements 50 are formed on the main surface of the device chip 5.

The transmission filter is formed so that an electrical signal of a desired frequency band can pass through. The transmission filter is a ladder filter including a plurality of series resonators and a plurality of parallel resonators.

The reception filter is formed so that an electrical signal of a desired frequency band can pass through. The reception filter is a ladder filter.

The sealing portion 17 is formed so as to cover the device chip 5. The sealing portion 17 is formed of an insulator such as a synthetic resin. In some examples, the sealing portion 17 is made of metal.

In case the sealing portion 17 is made of a synthetic resin, epoxy resin, polyimide, or the like can be used as the synthetic resin. Preferably, an epoxy resin is used to form the sealing portion 17 with a low temperature curing process.

FIG. 2 is a cross-sectional showing the device chip 5 of the acoustic wave device 1 according to the first embodiment.

As shown in FIG. 2, the device chip 5 includes a piezoelectric substrate 11, a medium layer 12, and a support substrate 13. The acoustic wave elements 50 are formed on the piezoelectric substrate 11.

The piezoelectric substrate 11 is, for example, a substrate made of a piezoelectric single crystal such as lithium tantalate, lithium niobate, or quartz. In another example, the piezoelectric substrate 11 is a substrate made of piezoelectric ceramics.

The thickness of the piezoelectric substrate 11 may be 0.3 μm to 5 μm for example.

The medium layer 12 includes a first acoustic impedance region 12A and a second acoustic impedance region 12B. The first acoustic impedance region 12A are made of, for example, silicon nitride, silicon oxynitride, silicon, alumina, silicon dioxide, or silicon carbide. The second acoustic impedance region 12B are made of, for example, alumina, aluminum nitride, silicon nitride, silicon oxynitride, silicon or silicon carbide, but is made of a material except the material employed in the first acoustic impedance region 12A.

The thickness of the medium layer 12 may be 0.5 μm to 2 μm for example.

In the embodiment shown in FIG. 2, the first acoustic impedance region 12A and the second acoustic impedance region 12B are arranged for three periods with respect to the four electrode fingers 51b on the piezoelectric substrate 11. That is, three second acoustic impedance regions 12B are arranged within the range of the four finger 51b. In other words, the first acoustic impedance region 12A and the second acoustic impedance region 12B are arranged at a different pitch from the pitch of the finger 51b.

As shown in FIG. 2, the second acoustic impedance region 12B may be formed to penetrate the first acoustic impedance region 12A. That is, the medium layers 12 may be formed so that the second acoustic impedance region 12B is exposed to both the piezoelectric substrate 11 side and the support substrate 13 side. The second acoustic impedance region 12B may be formed to have a thickness of one-half or more of the thickness of the medium layers 12.

According to another example, the medium layer 12 may be formed such that the second acoustic impedance region 12B are not exposed to the piezoelectric substrate 11 side.

Further, according to another example, the media layer 12 may be formed so that the second acoustic impedance region 12B are not exposed to the support substrate 13 side.

The support substrate 13 may be made of, for example, sapphire, silicon, alumina, spinel, silicon nitride, aluminum nitride, silicon carbide, silicon oxynitride, diamond, quartz, glass, or the like. The smaller thermal expansion coefficient and the higher the Young's modulus of the support substrate 13 is the better. This is because the temperature characteristic of the acoustic wave device 1 is improved. Since a sapphire substrate, which is a typical substrate satisfying such a condition, has high degree of hardness and is chemically stable, it is difficult to perform surface processing to have an uneven shape or a jagged shape and yield rate becomes low. Therefore, it is desirable that the support substrate 13 has a flat rectangular parallelepiped shape.

The thickness of the support substrate 13 may be, for example, 50 μm to 200 μm.

Next, an example of the acoustic wave element 50 formed on the piezoelectric substrate 11 will be described with reference to FIG. 3. FIG. 3 is a top view of the acoustic wave element 50 of the acoustic wave device 1 according to the first embodiment.

Although FIG. 3 does not show the piezoelectric substrate 11 to be transparent for convenience of explanation, the acoustic wave device 50 including IDT (Interdigital Transducer) electrodes 51 and a pair of reflectors 52 is formed on the main surface of the piezoelectric substrate 11 (as shown in FIG. 2). The IDT electrodes 51 and the pair of reflectors 52 are provided so as to excite acoustic waves (mainly SH waves).

The IDT electrodes 51 and the pair of reflectors 52 are made of an alloy of aluminum and copper for example. The IDT electrodes 51 and the pair of reflectors 52 are made of a suitable metal such as aluminum, molybdenum, iridium, tungsten, cobalt, nickel, ruthenium, chromium, strontium, titanium, palladium, or silver, or an alloy thereof.

The IDT electrodes 51 and the pair of reflectors 52 are formed of a laminated metal film in which a plurality of metal layers are laminated. The thicknesses of the IDT electrodes 51 and the pair of reflectors 52 have the thickness of 150 nm to 450 nm for example.

The IDT electrodes 51 include a pair of comb-shaped electrodes 51a. The pair of comb-shaped electrodes 51a are opposed to each other. The comb-shaped electrodes 51a include a plurality of electrode fingers 51b and a busbar 51c.

The plurality of fingers 51b are longitudinally aligned. The busbar 51c connects the plurality of fingers 51b.

One of the pair of reflectors 52 adjoins one side of the IDT electrodes 51. The other of the pair of reflectors 52 adjoins the other side of IDT electrodes 51.

A medium layer 12 formed between the piezoelectric substrate 11 and the support substrate 13 (not shown in FIG. 3) is formed. As shown in FIG. 3, each of the first acoustic impedance region 12A and the second acoustic impedance region 12B forms a stripe-shaped region having a longitudinal direction and a lateral direction. As shown in FIG. 3, the first acoustic impedance region 12A and the second acoustic impedance region 12B are alternately arranged in the lateral direction.

As shown in FIG. 3, the longitudinal directions of the first acoustic impedance region 12A and the second acoustic impedance region 12B are arranged in the same direction as the longitudinal direction of the finger 51b.

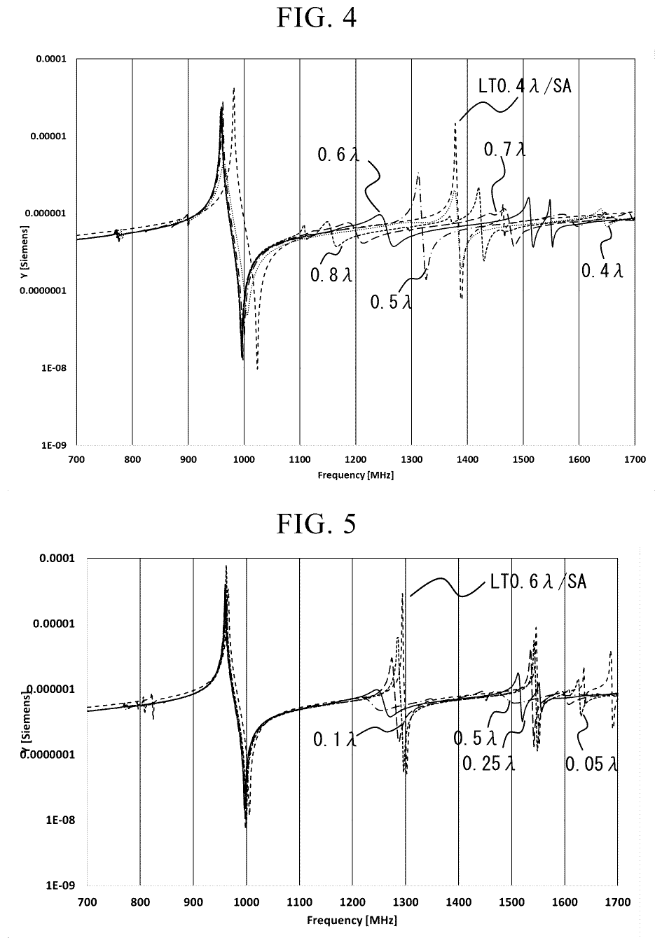

FIG. 4 is a diagram illustrating resonance characteristics of the acoustic wave device 1 according to the first embodiment and the resonator of the comparative example. The piezoelectric substrate 11 was made of lithium tantalate. The resonance characteristics of the acoustic wave device 1 was calculated by setting the thicknesses of the piezoelectric substrate 11 of 0.4 λ, 0.5 λ, 0.6 λ, 0.7 λ, and 0.8 λ when the wavelength of the acoustic wave determined by the pitch of the electrode fingers is λ.

The thickness of the medium layer 12 was 0.25 λ. In addition, the width of the first acoustic impedance region 12A and the width of the second acoustic impedance region 12B in the lateral direction are the same, that is, the duty ratio was 50%. The first acoustic impedance region 12A was made of silicon dioxide. The second acoustic impedance region 12B was made of alumina. The support substrate 13 was made of a sapphire substrate.

In the comparative example, lithium tantalate having a thickness of 0.4 λ is formed on the sapphire substrate, and the medium layer 12 is not included. Other structures in the comparative example are the same as those of the resonator of the acoustic wave device 1 according to the first embodiment.

In FIG. 4, a top peak and a bottom peak seen in the vicinity of 950 MHz to 1050 MHz are accompanied with the original resonant modes. A top peak and a bottom peak appear in the higher frequencies, here in the vicinity of 1100 MHz to 1700 MHz are based on unnatural resonant modes and are referred to as spurious. Since a strong spurious behavior drastically deteriorates characteristics when a filter or the like is formed by combining resonators, the smaller the height of the spurious top peak and the depth of the spurious bottom peak, the better the characteristics. As shown in FIG. 4, in the resonator of the acoustic wave device according to the first embodiment, spurious behavior is significantly improved compared to the resonance characteristic LT0.4/SA in the comparative example at any of the resonance characteristics 0.4 λ to 0.8 λ in the thickness from 0.4 λto 0.8 λ of the piezoelectric substrate 11.

FIG. 5 is a diagram (part 2) illustrating the resonance characteristics of the resonator of the acoustic wave device 1 according to the first embodiment and the resonator of the comparative example. The thickness of the piezoelectric substrate 11 was 0.6 λ. The resonance characteristics was calculated by setting the thickness of the medium layer 12 at 0.05 λ, 0.1 λ, 0.25 λ and 0.5 λ. Others are the same as described in FIG. 4. In the comparative example, lithium tantalate having a thickness of 0.6 λ is formed on the sapphire substrate, and the medium layer 12 is not included. Other structures in the comparative example are the same as those of the resonator of the acoustic wave device 1 according to the first embodiment.

As shown in FIG. 5, it can be seen that the spurious behavior of the resonator of the acoustic wave device according to the first embodiment is improved at all thickness of the medium layer 12 as compared with the comparative example. In particular, it can be seen that spurious behavior is significantly improved as compared with the comparative example when the thickness of the medium layer 12 is 0.1 λor more. Furthermore, it can be seen that the improvement to spurious behavior is greater when the thickness of the medium layer 12 is 0.25 λ and 0.5 λ.

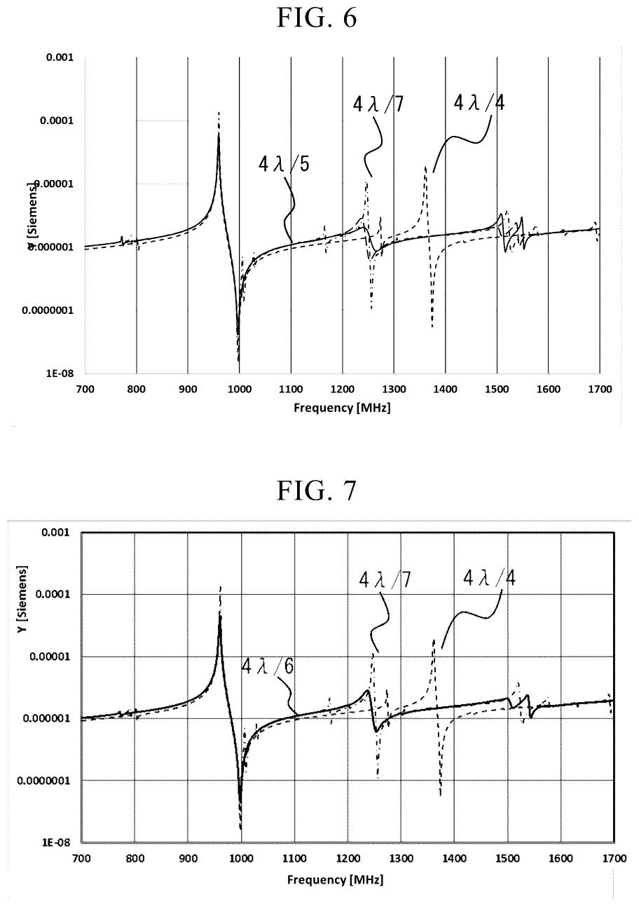

FIG. 6 is a diagram illustrating the resonance characteristics of the resonator (five periods within the range of eight electrode fingers, and others) of the acoustic wave device 1 according to the first embodiment.

The resonant property 4 λ/4 is the resonant property where the first acoustic impedance region 12A and the second acoustic impedance region 12B are arranged in four periods within a range where an electrode finger of 4 λ, that is, eight electrode fingers 51b are arranged. In other words, four second acoustic impedance regions 12B are arranged within the range of the eight electrode fingers 51b.

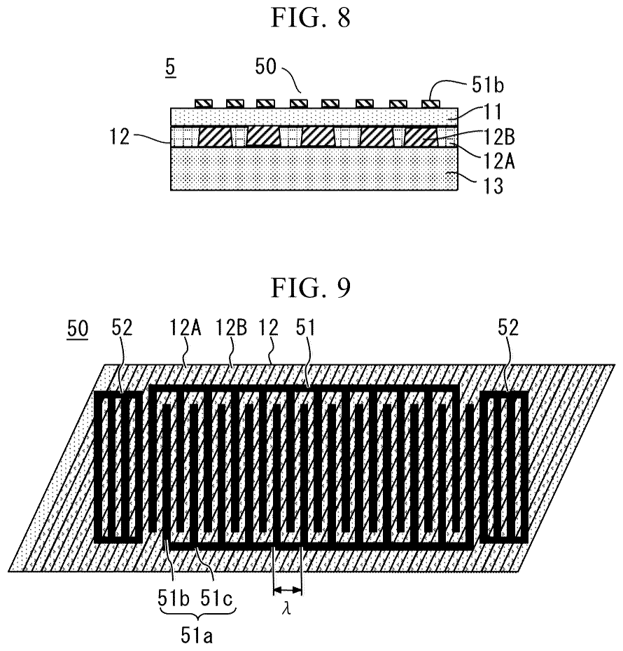

The resonant property 4 λ/5 is the resonant property where the first acoustic impedance region 12A and the second acoustic impedance region 12B are arranged in five periods within a range where an electrode finger of 4 λ, that is, eight electrode fingers 51b are arranged. In other words, five second acoustic impedance regions 12B are arranged within the eight electrode fingers 51b. FIG. 8 is a cross-sectional view showing a configuration in which five second acoustic impedance regions 12 B are arranged within the range of the eight electrode fingers 51b.

The resonant property 4 λ/7 is the resonant property where the first acoustic impedance region 12A and the second acoustic impedance region 12B are arranged in seven periods within a range where an electrode finger of 4 λ, that is, eight electrode fingers 51b are arranged. In other words, seven second acoustic impedance regions 12B are arranged within the range of the eight electrode fingers 51b.

FIG. 7 is a diagram illustrating the resonance characteristics of the resonator (six periods within the range of eight electrode fingers, and others) of the acoustic wave device 1 according to the first embodiment.

The resonant property 4 λ/6 is the resonant property where the first acoustic impedance region 12A and the second acoustic impedance region 12B are arranged in six periods within a range where an electrode finger of 4 λ, that is, eight electrode fingers 51b are arranged. In other words, six second acoustic impedance regions 12B are arranged within the range of the eight electrode fingers 51b. Further, in other words, three second acoustic impedance regions 12B are arranged within the range of the four finger 51b. The resonance characteristic 4 λ/4 and the resonance characteristic 4 λ/7 are the same as those described in FIG. 6.

As shown in FIG. 6 and FIG. 7, in the resonator of the acoustic wave device according to the first embodiment, spurious behavior is significantly improved when the first acoustic impedance region 12A and the second acoustic impedance region 12B are arranged in five or six periods within the range of the eight electrode fingers 51b.

This shows the results under the discrete conditions that the first acoustic impedance region 12A and the second acoustic impedance region 12B are arranged in four periods, five periods, six periods and seven periods within the range of the eight electrode fingers 51b, and shows the result of five periods and six periods is good. However, the period between five periods and six periods, for example, five-and-a-half periods (the number of the second acoustic impedance regions 12B is 11 in the range of 16 electrode fingers), it is reasonably expected to obtain good properties considering that the improvement effect is small when the ratio of the number of the electrode finger 51b and the number of the second acoustic impedance regions 12B is close to 2 or 1 times. That is, the scope of numbers of periods to obtain good properties has a width.

According to the first embodiment described above, it is possible to provide an acoustic wave device having superior temperature characteristics and more suppressing spurious.

### Second Embodiment

FIG. 9 is a top view of an acoustive wave element 50 of the acoustic wave device 1 according to a second embodiment. As shown in FIG. 9, the longitudinal direction of the first acoustic impedance region 12A and the longitudinal direction of the second acoustic impedance region 12B are arranged differently from the longitudinal direction of the electrode finger 51b. The arrangement like this makes the difference in characteristic acoustic impedance of the waves in the transverse-mode, and the transverse-mode spurious behavior can be reduced.

Since the other configuration is the same as that of the first embodiment, the description thereof will be omitted.

According to the second embodiment described above, it is possible to provide an acoustic wave device in which high-frequency spurious behavior is suppressed and transverse-mode spurious behavior is reduced.

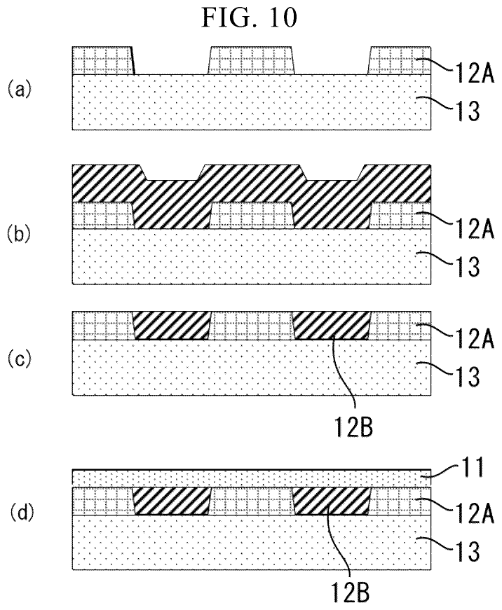

Next, a method for producing the acoustic wave device 1 according to the first embodiment will be described. FIG. 10 is a diagram for explaining a method for producing the acoustic wave device 1.

As shown in FIG. 10, a first acoustic impedance film is formed on the support substrate 13. Then, the first acoustic impedance film is patterned. In the patterning step, a method such as a lift-off method or an etching method is appropriately selected according to the material of the first acoustic impedance film.

As shown in FIG. 10, a second acoustic impedance material is filled in a region which the first acoustic impedance film is removed from by the patterning step. As the filling method of the second acoustic impedance material, a method such as a squeegee method, an evaporation method, or a sputtering method is appropriately selected according to the material.

As shown in FIG. 10, the second acoustic impedance material is polished until the first acoustic impedance film is exposed. In the polishing step, a chemical polishing method or a mechanical polishing method is appropriately selected according to the material.

As shown in FIG. 10, the piezoelectric substrate 11 is bonded after the polishing step. The acoustic wave elements 50 are configured to obtain desired device characteristics on the piezoelectric substrate 11 and the acoustic wave device 1 according to the first embodiment is obtained by the packaging process.

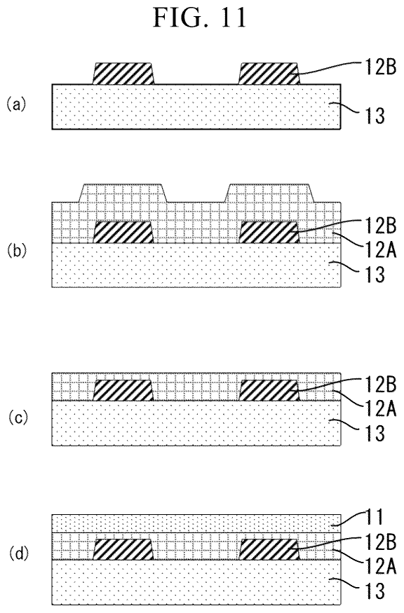

Next, a second method of producing the acoustic wave device 1 will be described. FIG. 11 is a diagram for explaining the second method for producing the acoustic wave device 1.

As shown in FIG. 11 part (a), a second acoustic impedance film is formed on the support substrate 13. Then, the second acoustic impedance film is patterned. In the patterning step, a method such as the lift-off method or the etching method is appropriately selected according to the material of the second acoustic impedance film.

As shown in FIG. 11 part (b), a first acoustic impedance material is filled in a region which the second acoustic impedance film is removed from by the patterning step. As the filling method of the first acoustic impedance material, a method such as the squeegee method, the evaporation method, or the sputtering method is appropriately selected according to the material.

As shown in FIG. 11 part (c), the first acoustic impedance material is polished. It may be polished until the second acoustic impedance film is exposed or not. In the polishing step, the chemical polishing method or the mechanical polishing method is appropriately selected according to the material.

As shown in FIG. 11 part (d), the piezoelectric substrate 11 is bonded after the polishing step. The acoustic wave elements 50 are configured to obtain desired device characteristics and the acoustic wave device 1 is obtained by the packaging process.

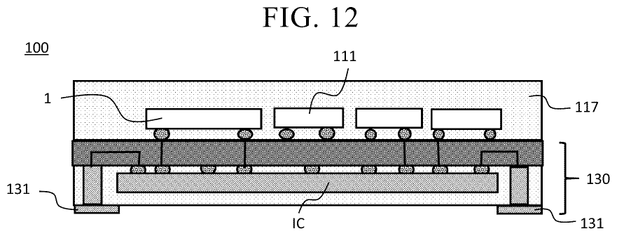

FIG. 12 is a longitudinal sectional view of a module to which the acoustic wave device 1 is applied according from the first embodiment to the third embodiment. The same or corresponding parts with the first embodiment to third embodiment are denoted by the same reference numerals. Duplicate descriptions of such portions may be simplified or omitted.

A module 100 includes a wiring substrate 130, a plurality of external connecting terminals 131, an integrated circuit component IC, the acoustic wave device 1, an inductor 111, and a sealing portion 117 in FIG. 12.

The plurality of external connection terminals 131 are formed on the lower surface of the wiring substrate 130. The plurality of external connection terminals 131 are mounted on the motherboard of the mobile communication terminal which is set in advance.

For example, the integrated circuit component IC is mounted inside the wiring substrate 130. The integrated circuit component IC includes a switching circuit and a low noise amplifier.

The acoustic wave device 1 is mounted on the main surface of the wiring substrate 130.

The inductor 111 is mounted on the main surface of the wiring substrate 130. The inductor 111 is mounted for impedance matching. For example, the inductor 111 is Integrated Passive Device (IPD).

The sealing portion 117 seals a plurality of electronic components including the acoustic wave device 1.

The module 100 described above includes the acoustic wave device 1. Therefore, it is possible to provide an acoustic wave device having superior temperature characteristics and more suppressing spurious.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is clamed is:

1. An acoustic wave device comprising:
a support substrate;
a medium layer formed on the support substrate;
a piezoelectric substrate formed on the medium layer; and
a resonator comprising IDT electrodes formed on the piezoelectric substrate,
wherein the medium layer comprises:
stripe-shaped first acoustic impedance regions having a longitudinal direction and a transverse direction; and
stripe-shaped second acoustic impedance regions having a longitudinal direction and a transverse direction and an acoustic impedance different from that of the first acoustic impedance regions, the stripe-shaped second acoustic impedance regions are alternately arranged with the first acoustic impedance regions.

2. The acoustic wave device according to claim 1, wherein the longitudinal directions of the first acoustic impedance region and the second acoustic impedance region are arranged along a same direction of an electrode finger of IDT electrode.

3. The acoustic wave device according to claim 1, wherein the first acoustic impedance regions and the second acoustic impedance regions are arranged at a pitch different from an electrode pitch of IDT electrode.

4. The acoustic wave device according to claim 1, wherein a thickness of the piezoelectric substrate is 0.4 λ or more and 1.0 λ or less when the wavelength of the acoustic wave determined by the pitch of the electrode fingers is λ.

5. The acoustic wave device according to claim 1, wherein a thickness of the medium layer is 0.1 λor more and 0.5 λor less when the wavelength of the acoustic wave determined by the pitch of the electrode fingers is λ.

6. The acoustic wave device according to claim 1, wherein the first acoustic impedance regions and the second acoustic impedance regions are arranged for three periods within the range of the four electrode fingers in cross-sectional view of the transverse directions of the first acoustic impedance regions and the second acoustic impedance regions.

7. The acoustic wave device according to claim 1, wherein the first acoustic impedance regions and the second acoustic impedance regions are arranged between five periods and six periods within the range of the eight electrode fingers in cross-sectional view of the transverse directions of the first acoustic impedance regions and the second acoustic impedance regions.

8. The acoustic wave device according to claim 1, wherein the first acoustic impedance regions comprises silicon dioxide.

9. The acoustic wave device according to claim 1, wherein the support substrate comprises sapphire, silicon, alumina, spinel, quartz, or glass.

10. A module comprising the acoustic wave device according to claim 1.
